(19) United States
(12) Patent Application Publication
(10) Pub. No.: US 2016/0099163 A1
(43) Pub. Date: Apr. 7, 2016

(54) SEMICONDUCTOR MANUFACTURING EQUIPMENT COMPONENT AND METHOD OF MAKING THE SAME

(71) Applicant: NGK SPARK PLUG CO., LTD., Nagoya-shi (JP)

(72) Inventors: Takakuni NASU, Komaki-shi (JP); Tomonori NIWA, Ichinomiya-shi (JP); Taichi KIBE, Komaki-shi (JP)

(21) Appl. No.: 14/870,115

(22) Filed: Sep. 30, 2015

(30) Foreign Application Priority Data
Oct. 1, 2014 (JP) 2014-203305

(51) Int. Cl. H01L 21/683; B32B 37/00; G03F 7/40; H01L 21/687

(52) U.S. Cl. CPC H01L 21/6833; H01L 21/68757; B32B 37/025; G03F 7/40; B32B 2310/0806; B32B 2315/02; B32B 2311/00; B32B 2398/00; B32B 2457/00

(57) ABSTRACT

A method of making a semiconductor manufacturing equipment component, such as an electrostatic chuck, includes an application step of applying a photosensitive metal paste onto a ceramic green sheet, which is to become the body substrate, the photosensitive metal paste being a heating element material; an exposure-and-development step of exposing the photosensitive metal paste, which has been applied onto the ceramic green sheet, to light and developing the photosensitive metal paste to form an intermediate heating element, which is to become the heating element, on the ceramic green sheet; and a firing step of co-firing the ceramic green sheet and the intermediate heating element to form the body substrate and the heating element.

### CROSS REFERENCE TO RELATED APPLICATIONS

The present application claims priority to Japanese Patent Application No. 2014-203305, which was filed on Oct. 1, 2014, the disclosure of which is herein incorporated by reference in its entirety.

### BACKGROUND OF THE INVENTION

1. Field of the Invention

The present invention relates to a semiconductor manufacturing equipment component and a method of making a semiconductor manufacturing equipment component.

2. Description of the Related Art

Existing semiconductor manufacturing equipment performs dry etching (such as plasma etching) or other processing of a semiconductor wafer (such as a silicon wafer). To increase the processing precision, it is necessary that the semiconductor manufacturing equipment have supporting means that can reliably support the semiconductor wafer in the equipment. An electrostatic chuck, which supports a semiconductor wafer by using an electrostatic attraction force, is known as the supporting means.

If the temperature of the semiconductor wafer varies, the processing precision decreases. To increase the processing precision, it is necessary to make the temperature of the semiconductor wafer, which is supported by the electrostatic chuck, be uniform. For example, Japanese Unexamined Patent Application Publication No. 2004-71647 describes an electrostatic chuck in which a heating element (heating electrode) is disposed in a ceramic substrate for supporting a semiconductor wafer. The heating element heats the semiconductor wafer.

However, the electrostatic chuck described in Japanese Unexamined Patent Application Publication No. 2004-71647 has the following problem. That is, the heating element is made by forming (patterning) a heating element material (metal paste) to have a desired pattern by screen printing. When screen printing is used, however, print staining, mesh marking of a screen mask, displacement of the screen mask, difference between the print direction and the patterning direction, and the like may occur. As a result, the patterned heating element material may have variations in thickness, width, and the like.

Therefore, the thickness and the width of the heating element after being fired may vary, and it is difficult for the heating element to generate heat uniformly. Thus, temperature variation (in the in-plane direction) of the ceramic substrate, in which the heating element is disposed, occurs, and therefore temperature variation of the semiconductor wafer, which is supported by the ceramic substrate, occurs. As a result, the processing precision of the semiconductor wafer may decrease.

### SUMMARY OF THE INVENTION

The present invention, which has been made against the aforementioned background, provides a semiconductor manufacturing equipment component in which variations in the thickness and the width of a heating element are suppressed and that can suppress temperature variation of a body substrate in which the heating element is disposed and a method of making the semiconductor manufacturing equipment component.

A first aspect of the present invention is a method of making a semiconductor manufacturing equipment component including a body substrate made of a ceramic and a heating element disposed in the body substrate, the method including an application step of applying a photosensitive metal paste onto a ceramic green sheet, which is to become the body substrate, the photosensitive metal paste being a heating element material; an exposure-and-development step of exposing to light the photosensitive metal paste that has been applied onto the ceramic green sheet and developing the photosensitive metal paste to form an intermediate heating element, which is to become the heating element, on the ceramic green sheet; and a firing step of co-firing the ceramic green sheet and the intermediate heating element to form the body substrate and the heating element. In other words, upon co-firing the ceramic green sheet and the intermediate heating element, the ceramic green sheet becomes the body substrate and the intermediate heating element becomes the heating element disposed in the body substrate.

In the method of making the semiconductor manufacturing equipment component, the application step and the exposure-and-development step are performed in this order. That is, the photosensitive metal paste (the heating element material) is formed to have a desired pattern by using photolithography. Therefore, variations in the thickness and the width of the intermediate heating element (the heating element material), which is formed by using photolithography, can be made smaller than those of a pattern formed by using an existing method, such as screen printing.

Thus, in the firing step, it is possible to form the heating element in which variations in thickness and width are suppressed and that can generate heat uniformly. Thus, temperature variation (temperature variation in the in-plane direction) of the body substrate, in which the heating element is disposed, can be suppressed. Moreover, temperature variation of the semiconductor wafer or the like, which is supported by the body substrate, can be suppressed. As a result, for example, the precision in etching the semiconductor wafer can be increased, and the yield can be improved.

Moreover, even if the pattern of the intermediate heating element (the heating element material), which is formed by using photolithography, includes lines having different line widths, variations in the thickness and the width of the pattern can be suppressed. Thus, for example, a heating element having a complex pattern including lines having different line widths can be formed with high precision.

A second aspect of the present invention is method of making a semiconductor manufacturing equipment component including a body substrate made of a ceramic and a heating element disposed in the body substrate, the method including an application step of applying a photosensitive metal paste onto a carrier film, the photosensitive metal paste being a heating element material; an exposure-and-development step of exposing to light the photosensitive metal paste that has been applied onto the carrier film and developing the photosensitive metal paste to form an intermediate heating element, which is to become the heating element, on the carrier film; a transfer step of transferring the intermediate heating element on the carrier film onto a ceramic green sheet, which is to become the body substrate; and a firing step of co-firing the ceramic green sheet and the intermediate heating element to form the body substrate and the heating element. In other words, upon co-firing the ceramic green sheet and the intermediate heating element, the ceramic green sheet becomes the body substrate and the intermediate heating element becomes the heating element disposed in the body substrate.

In the method of making the semiconductor manufacturing equipment, the application step, the exposure-and-development step, and the transfer step are performed in this order. That is, the photosensitive metal paste (the heating element material) is formed to have a desired pattern on the carrier film by using photolithography, and the intermediate heating element having the pattern is transferred onto the ceramic green sheet. Therefore, it is possible to obtain operational advantages the same as those of the method of making the semiconductor manufacturing equipment component according to the first aspect of the present invention described above.

A third aspect of the present invention is a semiconductor manufacturing equipment component including a body substrate made of a ceramic, and a heating element disposed in the body substrate, in which the heating element has a rectangular cross section.

In the semiconductor manufacturing equipment component, the heating element, which is disposed in the body substrate, has a rectangular cross section. Therefore, variations in the thickness and the width of the heating element are small, and the heating element can generate heat uniformly. Thus, temperature variation (temperature variation in the in-plane direction) of the body substrate, in which the heating element is disposed, can be suppressed. Moreover, temperature variation of the semiconductor wafer or the like, which is supported by the body substrate, can be suppressed. As a result, for example, the precision in etching the semiconductor wafer can be increased, and the yield can be improved.

As described above, with the present invention, it is possible to provide a semiconductor manufacturing equipment component in which variations in the thickness and the width of a heating element are suppressed and that can suppress temperature variation of a body substrate in which the heating element is disposed and a method of making the semiconductor manufacturing equipment component.

In the method of making a semiconductor manufacturing equipment component according to the first aspect or the second aspect, the intermediate heating element may have a rectangular cross section. In this case, variations in the thickness and the width of the intermediate heating element (the heating element material) can be suppressed. Thus, it is possible to obtain a heating element in which variations in the thickness and the width of the heating element are suppressed and that can generate heat uniformly. Here, the term “cross section” refers to, for example, a sectional surface of the intermediate heating element perpendicular to the longitudinal direction (axial direction) of the intermediate heating element. The same applies to the heating element described below. The term “rectangular” means that, for example, the shape of the cross section of the intermediate heating element is rectangular. The rectangular shape includes a substantially rectangular shape, such as a rectangular shape having slightly rounded corners.

The intermediate heating element may have a surface roughness Ra that is 1 μm or less. In this case, variations in the thickness and the width of the intermediate heating element (the heating element material) can be suppressed. Thus, it is possible to obtain a heating element in which variations in the thickness and the width of the heating element are suppressed and that can generate heat uniformly.

In the method of making the semiconductor manufacturing equipment component, in the application step, a photosensitive metal paste, which is a heating element material, is applied onto the ceramic green sheet. An existing known method, such as screen printing, can be used as the method of applying the photosensitive metal paste.

In the exposure-and-development step, the photosensitive metal paste, which has been applied onto the ceramic green sheet in the application step, is exposed to light and developed. Photosensitive metal pastes can be classified into “negative” pastes and “positive” pastes. When a negative photosensitive metal paste is used, portions of the paste to become the heating element are exposed to light and the other portions are not exposed to light. In the development operation, the unexposed portions are removed and the exposed portions are not removed. On the other hand, when a positive photosensitive metal paste is used, portions of the paste to become the heating element are not exposed to light and the other portions are exposed to light. In the development operation, the exposed portions are removed and the unexposed portions are not removed.

A “negative” photosensitive metal paste that can be used is, for example, a metal paste containing a metal powder (metal material), a photosensitive polymer, a photocurable agent, or the like. Existing known photosensitive polymers, photocurable agents, or the like can be used. A “positive” photosensitive metal paste that can be used is, for example, a metal paste containing a metal powder (metal material), a dissolution suppressant (polymer), a photodecomposition acceleration agent, or the like.

It is necessary that the metal powder (metal material) contained in the photosensitive metal paste have a melting point higher than the firing temperature of the body substrate, because in the firing step the body substrate and the heating element are formed by co-firing the ceramic green sheet and the intermediate heating element. Accordingly, tungsten (W), molybdenum (Mo), or an alloy of such metals may be used as the main component of the metal powder (metal material). The term “main component” means that a metal powder of, for example, tungsten or molybdenum, is contained in the photosensitive metal paste with a proportion of 50 volume % or more.

In the semiconductor manufacturing equipment component according to the third aspect, the heating element may have a surface roughness Ra that is 1 μm or less. In this case, variations in the thickness and the width of the heating element are small, and the heating element can generate heat uniformly.

Examples of the semiconductor manufacturing equipment component include a heating device for supporting and heating a semiconductor wafer or the like, an electrostatic chuck for holding a semiconductor wafer or the like by using an electrostatic attraction force, and a transport member for holding and transporting a semiconductor wafer or the like by using an electrostatic attraction force. In the heating device, the body substrate supports a semiconductor wafer or the like. The heating element, which is disposed in the body substrate, heats the semiconductor wafer or the like. In the electrostatic chuck or the transport member, a semiconductor wafer or the like is attracted to and held by the body substrate due to an electrostatic attraction force generated by an attraction electrode disposed in the body substrate. The heating element, which is disposed in the body substrate, heats the semiconductor wafer or the like.

The body substrate may include, for example, a stack of ceramic layers. With such a structure, various structures (such as the heating element and the like) can be easily formed in the body substrate.

The ceramic material of the body substrate may be a sintered compact or the like that is mainly composed of a high-temperature fired ceramic of, for example, alumina, yttria (yttrium oxide), aluminum nitride, boron nitride, silicon carbide, or silicon nitride.

Depending on use, the ceramic material of the body substrate may be a sintered compact that is mainly composed of a low-temperature fired ceramic, such as a glass ceramic in which inorganic ceramic filler, such as alumina, is added to borosilicate glass or borosilicate lead glass. A sintered compact that is mainly composed of a dielectric ceramic, such as barium titanate, lead titanate, strontium titanate, may be used.

Various technologies using plasma are used in processing operations, such as dry etching, of a semiconductor manufacturing process. In plasma processing, corrosive gases, such as halogen gases, are frequently used. Therefore, it is necessary that semiconductor manufacturing equipment components, such as an electrostatic chuck, that are exposed to plasma and corrosive gases, have high corrosion resistance. Accordingly, preferably, the body substrate is made of a ceramic material that is resistant to plasma and corrosive gases, such as a ceramic material that is mainly composed of alumina, yttria, or the like.

The main component of the metal material of the heating element, which is the same as that the metal powder (metal material) contained in the photosensitive metal paste, may be tungsten (W), molybdenum (Mo), or an alloy of such metals.

### BRIEF DESCRIPTION OF THE DRAWINGS

Illustrative aspects of the invention will be described in detail with reference to the following figures wherein:

FIG. 1 is a sectional view illustrating the structure of an electrostatic chuck according to a first embodiment.

FIG. 2A is a plan view illustrating an attraction electrode, and FIG. 2B is a plan view illustrating a via connected to the attraction electrode.

FIG. 3A is a plan view illustrating a heating element, FIG. 3B is a plan view illustrating vias connected to the heating element, FIG. 3C is a plan view illustrating drivers (internal conductive layers), and FIG. 3D is a plan view illustrating vias connected to the drivers.

FIG. 4A is a sectional view illustrating a step of forming a through-hole in a ceramic green sheet, and FIG. 4B is a sectional view illustrating a step of filling the through-hole with a via ink.

FIG. 5A is a sectional view illustrating a step of applying a photosensitive metal paste onto the ceramic green sheet, FIG. 5B is a sectional view illustrating a step of exposing the photosensitive metal paste to light, and FIG. 5C is a sectional view illustrating a step of developing the photosensitive metal paste.

FIG. 6 is a sectional view illustrating the sectional shape of the photosensitive metal paste (an intermediate heating element) on the ceramic green sheet.

FIG. 7 is a sectional view illustrating a step of stacking a plurality of ceramic green sheets.

FIG. 8A is a sectional view illustrating a step of applying a photosensitive metal paste onto a carrier film, FIG. 8B is a sectional view illustrating a step of exposing the photosensitive metal paste to light, and FIG. 8C is a sectional view illustrating a step of developing the photosensitive metal paste.

FIG. 9A is a sectional view illustrating a step of bonding a carrier film onto a ceramic green sheet, and FIG. 9B is a sectional view illustrating a step of transferring the photosensitive metal paste (an intermediate heating element) onto the ceramic green sheet.

FIG. 10 is a graph representing the result of analyzing the surface roughness of a heating element material (sample 11).

FIG. 11 is a graph representing the result of analyzing the surface roughness of a heating element material (sample 21).

FIG. 12 is a graph representing the relationship between the line width and the thickness of heating element materials (samples 12 and 22).

FIGS. 13A to 13C are photographs showing the sectional shapes of a heating element (sample 13) (FIG. 13A showing a line having a line width of 0.18 mm, FIG. 13B showing a line having a line width of 0.36 mm, and FIG. 13C showing a line having a line width of 0.72 mm).

FIG. 14 is a sectional view illustrating the sectional shape of the heating element (sample 13).

FIGS. 15A to 15C are photographs showing the sectional shapes of a heating element (sample 23) (FIG. 15A showing a line having a line width of 0.18 mm, FIG. 15B showing a line having a line width of 0.36 mm, and FIG. 15C showing a line having a line width of 0.72 mm).

FIG. 16 is a sectional view illustrating the sectional shape of the heating element (sample 23).

### DETAILED DESCRIPTION OF EXEMPLARY EMBODIMENTS OF THE INVENTION

Hereinafter, embodiments of the present invention will be described with reference to the drawings.

### A. First Embodiment

The present embodiment is an example in which a semiconductor manufacturing equipment component according to the present invention is applied to an electrostatic chuck.

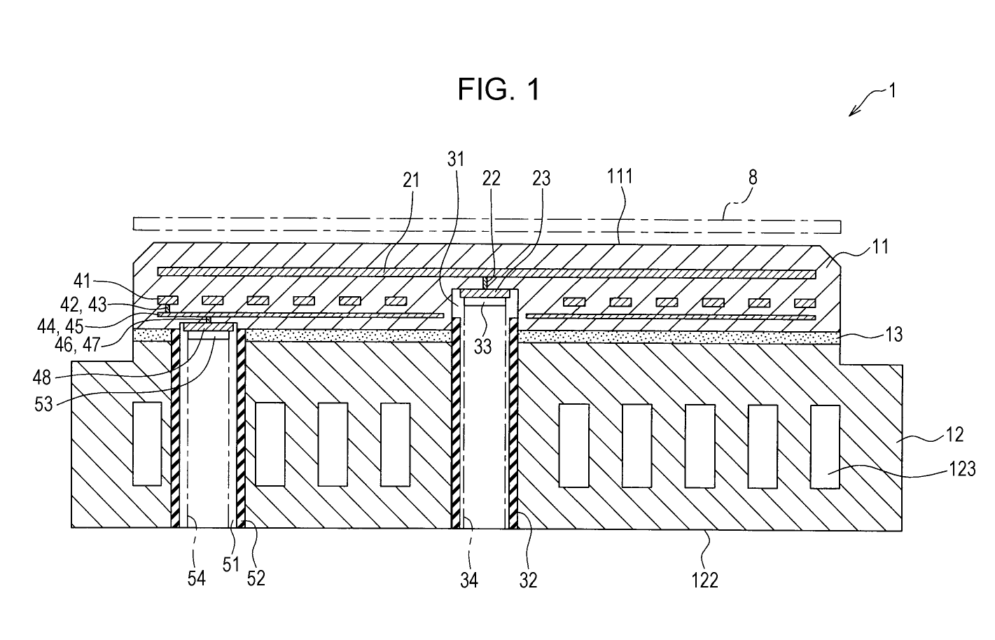

Referring to FIGS. 1 to 3D, an electrostatic chuck 1 (semiconductor manufacturing equipment component) includes a body substrate 11 made of a ceramic and a heating element 41 disposed in the body substrate 11. The heating element 41 has a rectangular cross section. Hereinafter, the electrostatic chuck 1 will be described in detail.

Referring to FIG. 1, the electrostatic chuck 1 attracts and holds a semiconductor wafer 8, which is an object to be held. The electrostatic chuck 1 includes the body substrate 11, a metal base 12, and an adhesive layer 13. The body substrate 11 and the metal base 12 are joined to each other through the adhesive layer 13 disposed therebetween.

In the present embodiment, the body substrate 11 is disposed above the metal base 12 in the vertical direction. The vertical direction is the direction in which the body substrate 11 and the metal base 12 are stacked and is the thickness direction of each of the body substrate 11 and the metal base 12. A direction perpendicular to the vertical direction (thickness direction) is a direction in which the electrostatic chuck 1 extends along a plane (planer direction, in-plane direction).

Referring to FIG. 1, the body substrate 11 is a member that attracts and holds the semiconductor wafer 8. The body substrate 11 is shaped like a disk having a diameter of 300 mm and a thickness of 3 mm. An upper surface 111 of the body substrate 11 is an attraction surface that attracts the semiconductor wafer 8. The body substrate 11 includes a stack of ceramic layers (not shown). The ceramic layers are each made of a sintered compact that is mainly composed of alumina.

An attraction electrode 21 and the heating element 41 (heating electrode) are disposed in the body substrate 11. The attraction electrode 21 is disposed substantially in a plane in the body substrate 11. The attraction electrode 21 generates an electrostatic attraction force when a direct-current high voltage is applied thereto. Due to the electrostatic attraction force, the semiconductor wafer 8 is attracted to and held by the upper surface 111 (attraction surface) of the body substrate 11. The attraction electrode 21 is made of tungsten.

The heating element 41 is disposed in the body substrate 11 at a position below the attraction electrode 21 (that is, on the metal base 12 side of the attraction electrode 21). The heating element 41 is disposed substantially in a plane in the body substrate 11. The heating element 41 has a rectangular cross section. The heating element 41 has a surface roughness Ra that is 1 μm or less. The heating element 41 is made of tungsten. Besides tungsten, molybdenum, an alloy of tungsten and molybdenum, or the like can be used as the material of the attraction electrode 21 and the heating element 41. Compared with a case where gold or silver is used as the material of the attraction electrode 21 and the heating element 41, the production costs of the ceramic multilayer substrate can be reduced.

Referring to FIG. 1, the metal base 12 is a metallic cooling member (cooling plate) made of aluminum or an aluminum alloy. The metal base 12 is shaped like a disk having a diameter of 340 mm and a thickness of 32 mm. The metal base 12 body is disposed below the body substrate 11. A coolant passage 123, through which a coolant (such as a fluorinated liquid or pure water) flows, is formed in the metal base 12.

Referring to FIG. 1, the adhesive layer 13 is disposed between the body substrate 11 and the metal base 12. The adhesive layer 13 is made from an adhesive that is composed of a silicone resin. The body substrate 11 is joined to the metal base 12 through the adhesive layer 13.

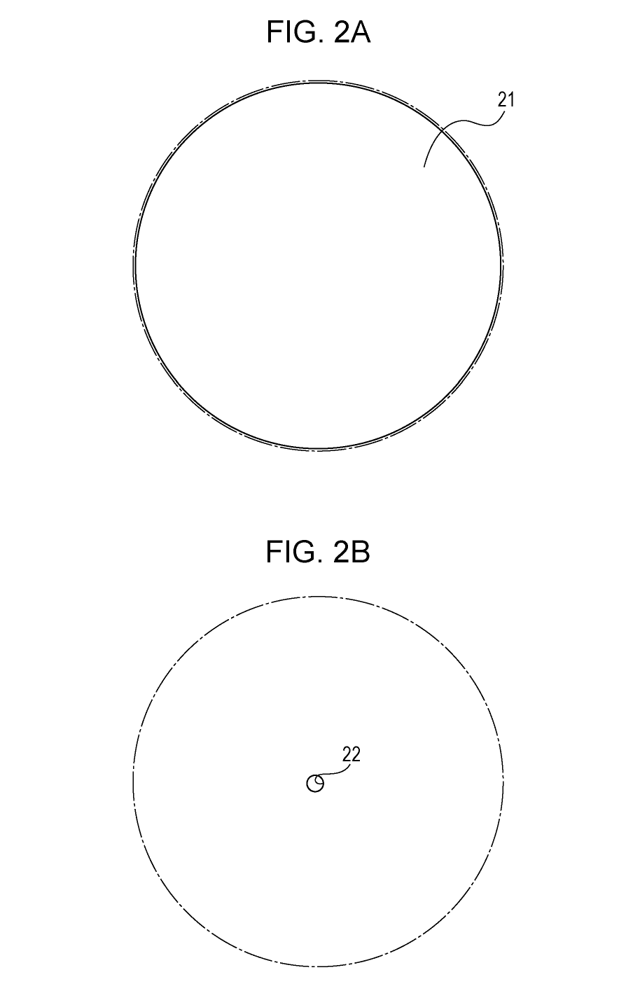

Referring to FIG. 2A, the attraction electrode 21 is disposed substantially in a plane in the body substrate 11 as described above. The attraction electrode 21 has a circular shape in a plan view.

Referring to FIG. 2B, a via 22 is disposed below (on the metal base 12 side of) the attraction electrode 21. The via 22 extends in the vertical direction along the central axis of the body substrate 11. The via 22 is connected to the attraction electrode 21.

Referring to FIG. 1, an inner hole 31 is formed in the electrostatic chuck 1 so as to extend in the vertical direction from a lower surface 122 of the metal base 12 toward the body substrate 11. A cylindrical insulation member 32 is fitted into the inner hole 31. A metallized layer 23 is disposed on the bottom surface of the inner hole 31. The metallized layer 23 is connected to the via 22. That is, the attraction electrode 21 is connected to the metallized layer 23 through the via 22.

An internal connection terminal 33 is disposed on the metallized layer 23. A terminal metal piece 34 is attached to the internal connection terminal 33. The terminal metal piece 34 is connected to a power circuit (not shown). Electric power for generating an electrostatic attraction force is supplied to the attraction electrode 21 through components including the internal connection terminal 33.

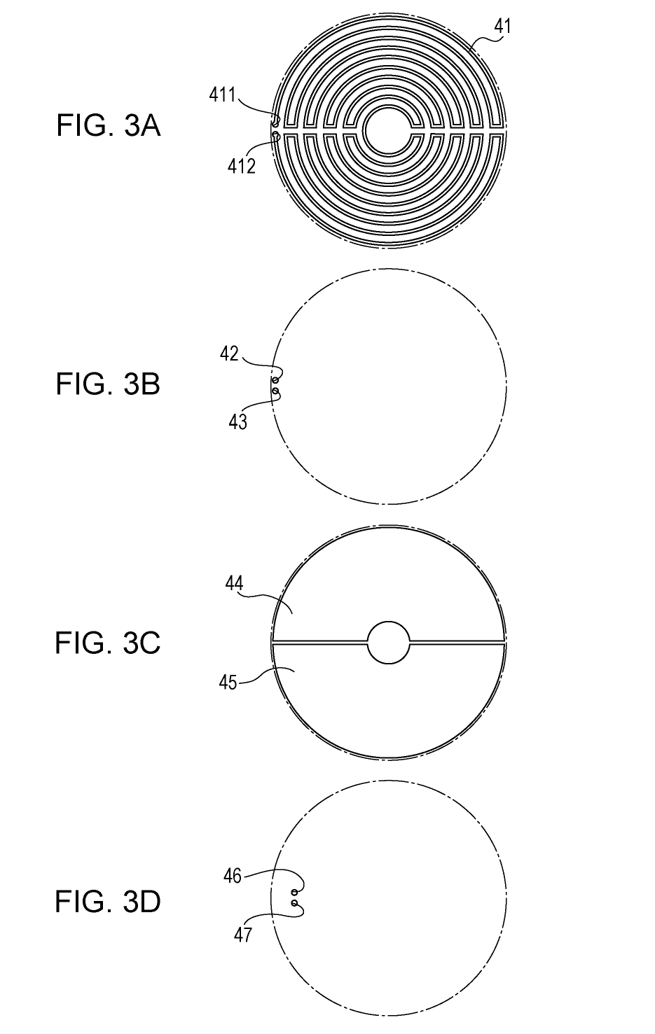

Referring to FIG. 3A, the heating element 41 is disposed substantially in a plane in the body substrate 11 as described above. The heating element 41, which is an elongated single element, is bent multiple times and disposed substantially concentrically.

Referring to FIG. 3B, a pair of vias 42 and 43 are disposed below (on the metal base 12 side of) the heating element 41. The pair of vias 42 and 43 are respectively connected to a pair of terminal portions 411 and 412 of the heating element 41.

Referring to FIG. 3C, a pair of drivers 44 and 45 (internal conductive layers) are disposed below (on the metal base 12 side of) the pair of vias 42 and 43. The pair of drivers 44 and 45 are respectively connected to the pair of vias 42 and 43. Each of the drivers 44 and 45 has a substantially semicircular shape in a plan view.

Referring to FIG. 3D, a pair of vias 46 and 47 are disposed below (on the metal base 12 side of) the pair of drivers 44 and 45. The pair of vias 46 and 47 are respectively connected to the pair of drivers 44 and 45.

Referring to FIG. 1, an inner hole 51 is formed in the electrostatic chuck 1 so as to extend in the vertical direction from the lower surface 122 of the metal base 12 toward the body substrate 11. A cylindrical insulation member 52 is fitted into the inner hole 51. A pair of metallized layers 48 (one of which is shown in FIG. 1) are disposed on the bottom surface of the inner hole 51. The pair of metallized layers 48 are respectively connected to the pair of vias 46 and 47. That is, the heating element 41 is (the terminal portions 411 and 412 are) connected to the metallized layers 48 through the vias 42 and 43, the drivers 44 and 45, and the vias 46 and 47.

An internal connection terminal 53 is disposed on each of the metallized layers 48. A terminal metal piece 54 is attached to each of the internal connection terminals 53. The terminal metal pieces 54 are connected to a power circuit (not shown). Electric power for heating the heating element 41 is supplied to the heating element 41 through components including the internal connection terminals 53.

Although not illustrated, a cooling gas supply passage is formed in the electrostatic chuck 1 (the body substrate 11, the metal base 12, and the adhesive layer 13). A cooling gas for cooling the semiconductor wafer 8, such as helium, is supplied through the cooling gas supply passage. A plurality of cooling openings (not shown) and an annular cooling groove (not shown) are formed in the upper surface 111 (attraction surface) of the body substrate 11. The cooling openings are outlets of the cooling gas supply passage. The annular cooling groove is formed so that the cooling gas, which is supplied through the cooling openings, can be spread over the entirety of the upper surface 111 (attraction surface) of the body substrate 11.

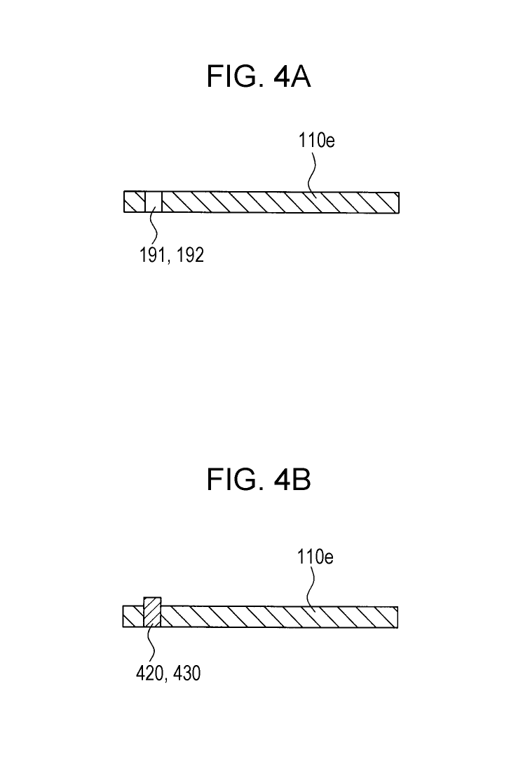

Next, a method of making the electrostatic chuck 1 (semiconductor manufacturing equipment component) will be described. Referring to FIGS. 4A to 7, the method of making the electrostatic chuck 1 (semiconductor manufacturing equipment component) includes an application step of applying a photosensitive metal paste 410 onto a ceramic green sheet 110e, which is to become the body substrate 11, the photosensitive metal paste being a heating element material; an exposure-and-development step of exposing the photosensitive metal paste 410, which has been applied onto the ceramic green sheet 110e, to light and developing the photosensitive metal paste 410 to form an intermediate heating element 410a, which is to become the heating element 41, on the ceramic green sheet 110e; and a firing step of co-firing the ceramic green sheet 110e and the intermediate heating element 410a to form the body substrate 11 and the heating element 41. Hereinafter, the method of making the electrostatic chuck 1 will be described in detail.

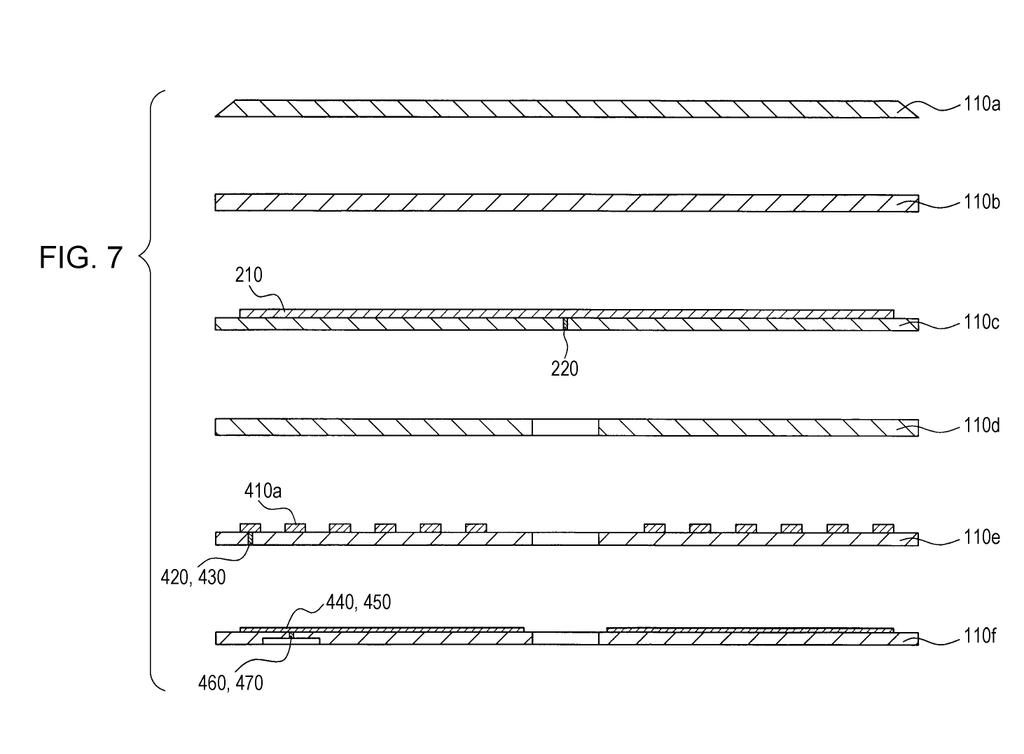

First, in step 1, a ceramic green sheet, which is mainly composed of alumina, is made by using a known method. In the present embodiment, six ceramic green sheets 110a to 110f (see FIG. 7), which are to become the body substrate 11, are made.

Referring to FIG. 4A, in step 2, a pair of through-holes 191 and 192 are formed in the ceramic green sheet 110e (see FIG. 7) by using a method such as punching. The pair of through-holes 191 and 192 are formed at positions at which the pair of vias 42 and 43 are to be formed.

Referring to FIG. 4B, in step 3, the pair of through-holes 191 and 192 in the ceramic green sheet 110e are respectively filled with via inks 420 and 430 by using a metal mask or the like. Each of the via inks 420 and 430 is a metallized ink that is a slurry mixture made by mixing the material powder of the ceramic green sheet, which is mainly composed of alumina, with a tungsten powder.

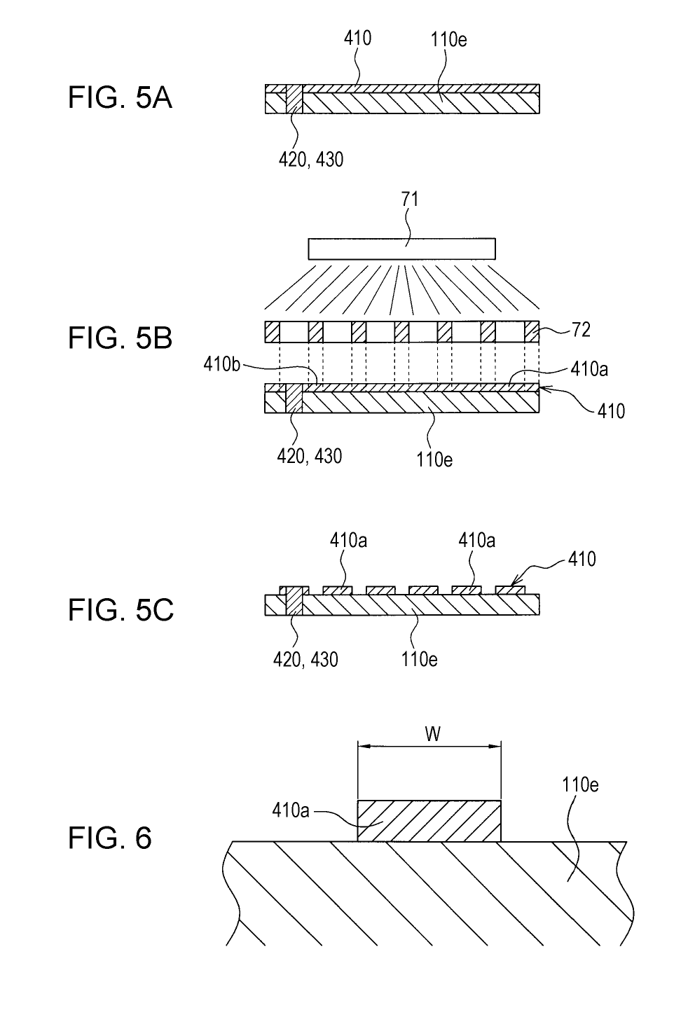

Referring to FIG. 5A, in step 4, the photosensitive metal paste 410 is applied onto the ceramic green sheet 110e by screen printing. The photosensitive metal paste 410 is applied onto the entirety of a surface of the ceramic green sheet 110e. The photosensitive metal paste 410 includes a tungsten powder, a photosensitive polymer, a photocurable agent, and other such materials. The photosensitive metal paste 410 may have a viscosity in the range of 100 to 20000 poise and an application thickness in the range of 5 to 30 μm. The applied photosensitive metal paste 410 is dried for 5 to 30 minutes at a temperature in the range of 80 to 120° C.

Referring to FIG. 5B, in step 5, a glass mask 72 is disposed above the ceramic green sheet 110e while adjusting the position of the glass mask 72. Predetermined portions of the photosensitive metal paste 410 on the ceramic green sheet 110e are irradiated with light (ultraviolet radiation) that is emitted from an exposure device 71 through the glass mask 72. As a light source, a mercury lamp (g-line, h-line) or the like can be used. The exposure energy may be in the range of 200 to 6000 mj. As the exposure device 71, a laser direct imager (LDI), for example, is used. As the glass mask 72, a photomask including transmitting portions that transmit ultraviolet radiation and blocking portions that block ultraviolet radiation is used.

At this time, portions of the photosensitive metal paste 410 to become the heating element 41 are irradiated with light. Thus, the portions of the photosensitive metal paste 410 irradiated with light (exposed portions) are cured and the intermediate heating element 410a is formed. Portions of the photosensitive metal paste 410 that are not irradiated with light (unexposed portions) become unexposed portions 410b.

Referring to FIG. 5C, in step 6, the portions of the photosensitive metal paste 410 other than the intermediate heating element 410a (the unexposed portions 410b) are removed. To be specific, the ceramic green sheet 110e, to which the photosensitive metal paste 410 has been applied, is immersed in a developer. One such developer is an aqueous solution containing 0.1 to 5 mass % of sodium carbonate. Thus, the unexposed portions 410b of the photosensitive metal paste 410 are removed and the intermediate heating element 410a remains. Subsequently, washing and drying are performed. Drying is performed for 5 to 30 minutes at a temperature in the range of 80 to 120° C.

Referring to FIG. 6, the intermediate heating element 410a on the ceramic green sheet 110e has a rectangular cross section. The intermediate heating element 410a has a surface roughness Ra that is 1 μm or less. The intermediate heating element 410a may have a pattern width W (line width) in the range of 20 to 2000 μm. FIG. 6 shows a cross section that is perpendicular the longitudinal direction (axial direction) of the intermediate heating element 410a.

Referring to FIG. 7, in step 7, necessary portions of the ceramic green sheets 110c and 110f, other than the ceramic green sheet 110e, are filled with the aforementioned metallized ink.

To be specific, a through-hole is formed in the ceramic green sheet 110c by using a method such as punching. The through-hole is filled with a via ink 220, which is to become the via 22, by using a metal mask or the like. Subsequently, an electrode ink 210, which is to become the attraction electrode 21, is applied onto the ceramic green sheet 110c by using a method such as screen printing. The via ink 220 and the electrode ink 210 are each the aforementioned metallized ink.

A pair of through-holes are formed in the ceramic green sheet 110f by using a method such as punching. The pair of through-hole are filled with via inks 460 and 470, which are to respectively become the pair of vias 46 and 47, by using a metal mask or the like. Subsequently, driver inks 440 and 450, which are respectively to become the drivers 44 and 45, are applied onto the ceramic green sheet 110f by using a method such as screen printing. The via inks 460 and 470 and the driver inks 440 and 450 are each the aforementioned metallized ink.

Through-holes are formed in portions of the ceramic green sheets 110d to 110f to become the inner hole 31 (the through-hole is not illustrated in FIG. 5A to 5C). A recess is formed in a portion of the ceramic green sheet 110f to become the inner hole 51.

In step 8, the ceramic green sheets 110a to 110f (see FIG. 7) are stacked and thermocompression bonded. Thus, a stacked sheet including the ceramic green sheets 110a to 110f, the intermediate heating element 410a is formed. The stacked sheet is cut into a predetermined shape. Subsequently, the stacked sheet is co-fired in reducing atmosphere for 5 hours at a temperature in the range of 1400 to 1800° C. (for example, 1450° C.). As a result, alumina in the ceramic green sheets 110a to 110f, tungsten in the electroconductive paste, and tungsten in the photosensitive metal paste 410 (the intermediate heating element 410a) are simultaneously sintered. The ceramic green sheets 110a to 110f become an alumina sintered compact, and the photosensitive metal paste 410 (the intermediate heating element 410a) becomes the heating element 41.

In step 9, components including the metallized layers 23 and 48 are formed on necessary portions of the alumina sintered compact. Thus, the body substrate 11 is obtained. Subsequently, the body substrate 11 and the metal base 12 are joined to each other by using an adhesive composed of a silicone resin. Thus, the electrostatic chuck 1, in which the body substrate 11 and the metal base 12 are joined to each other through the adhesive layer 13, is obtained.

In the present embodiment, alumina is used as the ceramic material of the body substrate 11. If, for example, aluminum nitride is used as the ceramic material, in step 8, the stacked sheet is co-fired in reducing atmosphere for 5 hours at a temperature in the range of 1600 to 2000° C.

Next, operational advantages of the present embodiment will be described. In the method of making the electrostatic chuck 1 (semiconductor manufacturing equipment component) according to the present embodiment, the application step, the exposure step, and the development step are performed. That is, the heating element material (the photosensitive metal paste 410) is formed to have a desired pattern by using photolithography. Therefore, variations in the thickness and the width of the pattern of the heating element material (the intermediate heating element 410a), which is formed by using photolithography, can be made smaller than those of a pattern formed by using an existing method, such as screen printing.

Thus, in the firing step, it is possible to form the heating element 41 in which variations in thickness and width are suppressed and that can generate heat uniformly. Accordingly, temperature variation (temperature variation in the in-plane direction) of the body substrate 11, in which the heating element 41 is disposed, can be suppressed. Moreover, temperature variation of the semiconductor wafer 8, which is supported by the body substrate 11, can be suppressed. As a result, for example, the precision in etching the semiconductor wafer 8 can be increased, and the yield can be improved.

Moreover, even if the pattern of the heating element material (the intermediate heating element 410a), which is formed by using photolithography, includes lines having different line widths, variations in the thickness and the width of the pattern can be suppressed. Thus, for example, the heating element 41 having a complex pattern including lines having different line widths can be formed with high precision.

In the method according to the present embodiment, the intermediate heating element 410a has a rectangular cross section. Therefore, variations in the thickness and the width of the heating element material (the intermediate heating element 410a) can be suppressed. Thus, it is possible to obtain the heating element 41 in which variations in thickness and width are suppressed and that can generate heat uniformly.

The intermediate heating element 410a has a surface roughness Ra of 1 μm or less. Therefore, variations in the thickness and the width of the heating element material (the intermediate heating element 410a) can be suppressed. Thus, it is possible to obtain the heating element 41 in which variations in thickness and width are suppressed and that can generate heat uniformly.

In the electrostatic chuck 1 (the semiconductor manufacturing equipment component) according to the present embodiment, the heating element 41, which is disposed in the body substrate 11, has a rectangular cross section. Therefore, variations in the thickness and the width of the heating element 41 are small, and the heating element 41 can generate heat uniformly. Thus, temperature variation (temperature variation in the in-plane direction) of the body substrate 11, in which the heating element 41 is disposed, can be suppressed. Moreover, temperature variation of the semiconductor wafer 8, which is supported (held) by the body substrate 11, can be suppressed. As a result, for example, the precision in processing, such as etching, of the semiconductor wafer 8 can be increased, and the yield can be improved.

In the present embodiment, the heating element 41, which is disposed in the body substrate 11, has a surface roughness Ra that is 1 μm or less. Therefore, variations in the thickness and the width of the heating element 41 are small, and the heating element 41 can generate heat uniformly.

As described above, with the present embodiment, it is possible to provide the electrostatic chuck 1 (semiconductor manufacturing equipment component) in which variations in the thickness and the width of the heating element 41 are suppressed and that can suppress temperature variation of the body substrate 11, in which the heating element 41 is disposed, and to provide a method of making the electrostatic chuck 1.

### B. Second Embodiment

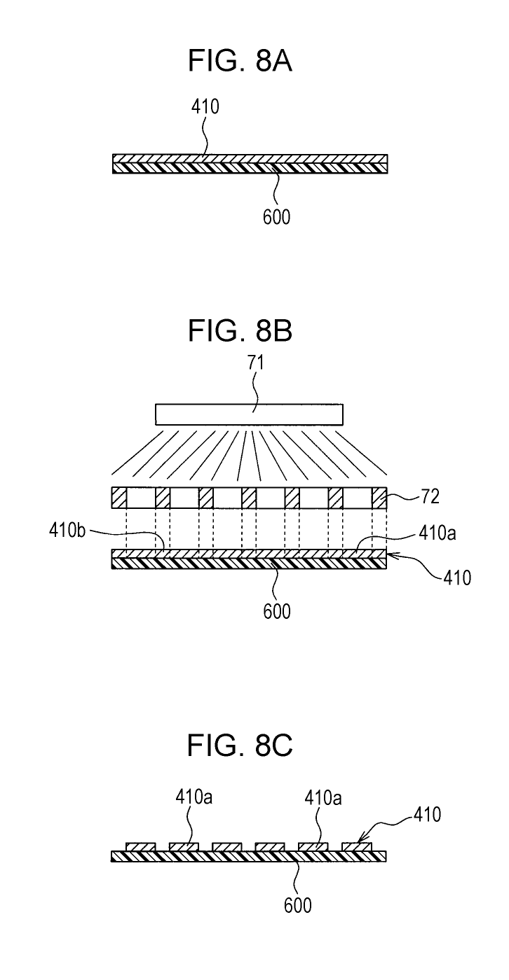

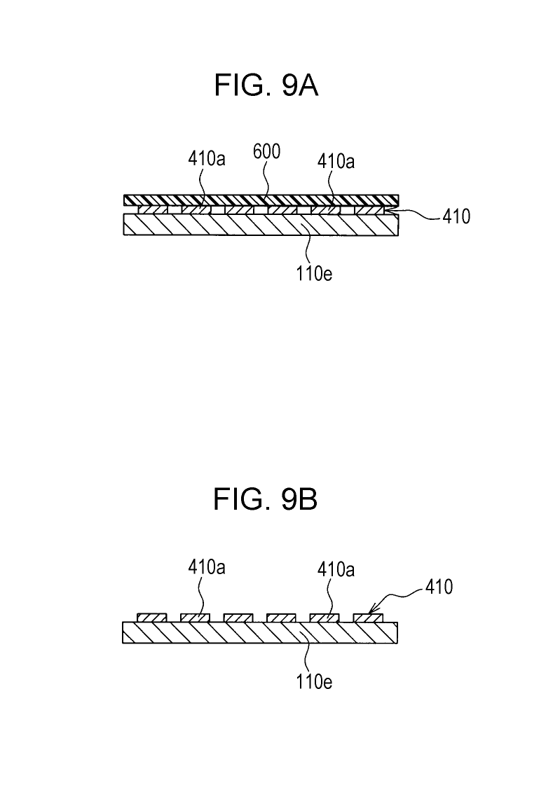

FIGS. 8A to 9B illustrate a second embodiment, which is a modified example of the method of making the electrostatic chuck 1 (see FIGS. 1 to 3D) according to the first embodiment described above.

Referring to FIGS. 8A to 9B, the method of making the electrostatic chuck 1 (semiconductor manufacturing equipment component) according to the present embodiment includes an application step of applying the photosensitive metal paste 410 onto a carrier film 600, the photosensitive metal paste 410 being a heating element material; an exposure-and-development step of exposing the photosensitive metal paste 410, which has been applied onto the carrier film 600, to light and developing the photosensitive metal paste 410 to form the intermediate heating element 410a, which is to become the heating element 41, on the carrier film 600; a transfer step of transferring the intermediate heating element 410a on the carrier film 600 onto a ceramic green sheet 110e, which is to become the body substrate 11; and a firing step of co-firing the ceramic green sheet 110e and the intermediate heating element 410a to form the body substrate 11 and the heating element 41.

The present embodiment differs from the first embodiment in steps 4 to 6 and is the same as the first embodiment in steps 1 to 3 and 7 to 9. Hereinafter, steps 4 to 6, which differ from those of the first embodiment, will be mainly described.

Referring to FIG. 8A, in step 4A, the photosensitive metal paste 410 is applied onto the carrier film 600, which is made of a resin, by using a coater or the like. The photosensitive metal paste 410 is applied onto the entirety of a surface of the carrier film 600. The applied photosensitive metal paste 410 is dried for 5 to 30 minutes at a temperature in the range of 80 to 120° C. The carrier film 600 in the present embodiment is made of polyethylene naphthalate (PEN). Alternatively, the carrier film 600 may be made of polyethylene terephthalate (PET), polyphenylene sulfide (PPS), polyimide resin, or the like.

Referring to FIG. 8B, in step 5A, the glass mask 72 is disposed above the carrier film 600 while adjusting the position of the glass mask 72. Predetermined portions of the photosensitive metal paste 410 on the carrier film 600 are irradiated with light (ultraviolet radiation) that is emitted from the exposure device 71 through the glass mask 72.

At this time, portions of the photosensitive metal paste 410 to become the heating element 41 are irradiated with light. Thus, the portions of the photosensitive metal paste 410 irradiated with light (exposed portions) are cured and the intermediate heating element 410a is formed. Portions of the photosensitive metal paste 410 that are not irradiated with light (unexposed portions) become the unexposed portions 410b.

Referring to FIG. 8C, in step 6A-1, portions of the photosensitive metal paste 410 other than the intermediate heating element 410a (the unexposed portions 410b) are removed. To be specific, the carrier film 600, to which the photosensitive metal paste 410 has been applied, is immersed in a developer. Thus, the unexposed portions 410b of the photosensitive metal paste 410 are removed and the intermediate heating element 410a remains. Subsequently, washing and drying are performed. Drying is performed for 5 to 30 minutes at a temperature in the range of 80 to 120° C.

Referring to FIG. 9A, in step 6A-2, the carrier film 600, on which the intermediate heating element 410a has been formed, is bonded (compressively bonded) onto the ceramic green sheet 110e. At this time, the carrier film 600 is bonded (compressively bonded) onto the ceramic green sheet 110e so that the intermediate heating element 410a on the carrier film 600 is placed on the ceramic green sheet 110e.

Referring to FIG. 9B, in step 6A-3, the carrier film 600 is peeled off the ceramic green sheet 110e. Thus, the intermediate heating element 410a is transferred onto the ceramic green sheet 110e. That is, the intermediate heating element 410a is formed on the ceramic green sheet 110e.

Next, operational advantages of the present embodiment will be described.

In the method of making the electrostatic chuck 1 (semiconductor manufacturing equipment component) according to the present embodiment, the application step, the exposure-and-development step, and the transfer step are performed in this order. That is, the heating element material (the photosensitive metal paste 410) is formed on the carrier film 600 to have a desired pattern by using photolithography, and the intermediate heating element 410a having the pattern is transferred onto the ceramic green sheet 110e. Therefore, it is possible to obtain operational advantages the same as those of the method of making the electrostatic chuck 1 (semiconductor manufacturing equipment component) according to the first embodiment described above.

The method according to the present embodiment is suitable for a case where the ceramic green sheet 110e is made of a material that tends to react with water. Aluminum nitride is an example of a material that tends to react with water (2AlN+3H₂O→2NH₃+Al₂O₃). For example, in a case where a sodium carbonate aqueous solution is used as the developer, the developer reacts with the ceramic green sheet 110e. However, with the method according to the present embodiment, such a problem does not occur, because contact between the developer and the ceramic green sheet 110e does not occur. Therefore, the method according to the present embodiment is suitable for such a case.

### Example

In the present example, variations of the surface roughness and the thickness of heating element materials patterned by using different methods were evaluated. The shapes of heating elements obtained by co-firing the heating element materials, which were patterned by using different methods, and the ceramic green sheet were observed.

First, by using a photosensitive metal paste (heating element material) the same as that of the first embodiment, a pattern was formed on a ceramic green sheet (alumina green sheet) by photolithography in the same way as in the first embodiment (sample 11). For comparison, by using an existing metal paste (heating element material), a pattern was formed on a ceramic green sheet by screen printing (sample 21). In each of the samples 11 and 21, the line width was 0.70 mm.

Next, by using a contact profilometer (SURFCOM 1500SD3, made by Tokyo Seimitsu Co., Ltd.), the surface roughnesses of the heating element materials of the samples 11 and 21 were analyzed. The measurement conditions were as follows: measuring range, 1000 μm; minimum resolution, 0.0001 μm; measuring force, 0.75 mN; stylus material, diamond; stylus shape, 60° conical; and measuring speed, 0.5 mm/s.

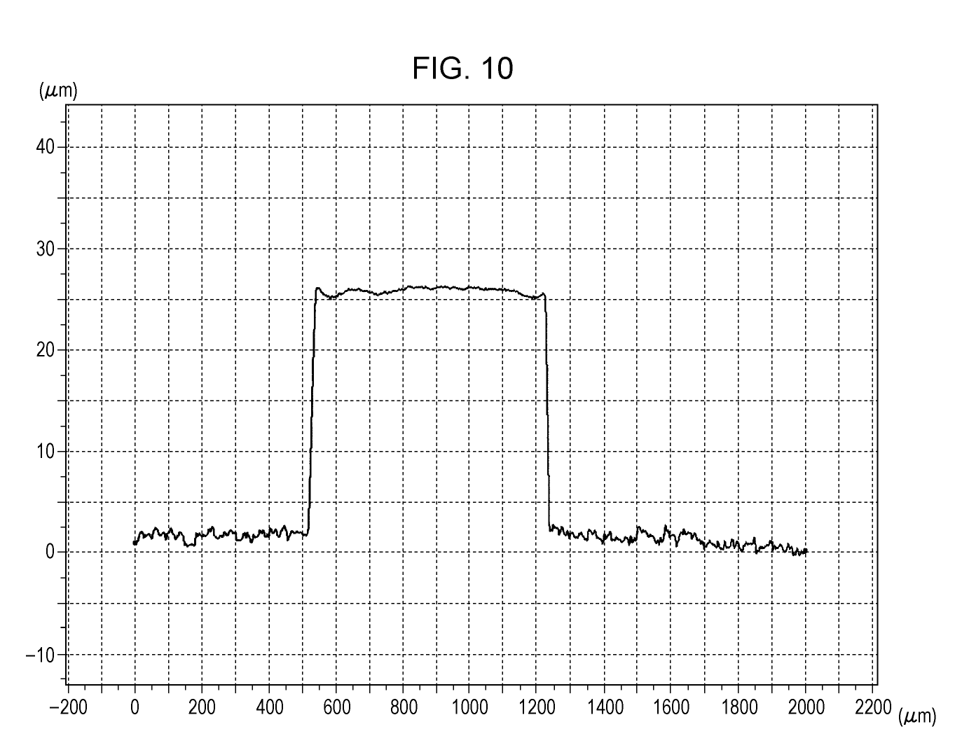

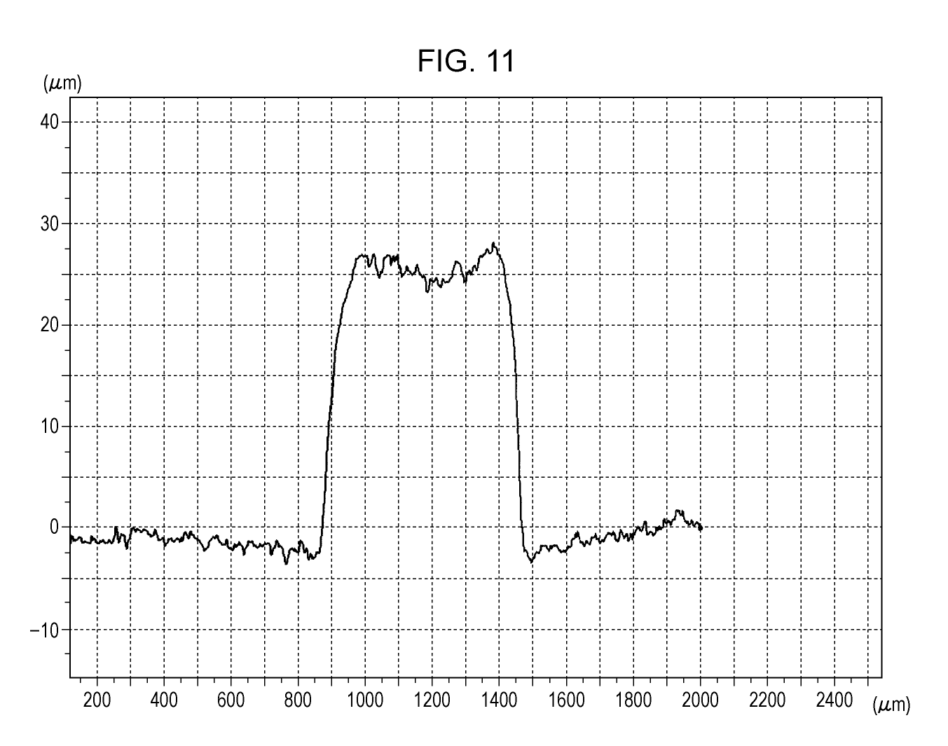

FIG. 10 shows the result of analyzing the surface roughness of the heating element material of the sample 11. FIG. 11 shows the result of analyzing the surface roughness of the heating element material of the sample 21. Comparing FIG. 10 and FIG. 11, it can be seen that the surface roughness of the sample 11, which was formed by photolithography, was smaller than that of the sample 21, which was formed by screen printing. Referring to FIG. 10, it can be seen that the cross-sectional shape of the heating element material of the sample 11 was rectangular.

Next, by using the photosensitive metal paste (heating element material), patterns having four different line widths were simultaneously formed on a ceramic green sheet by photolithography (sample 12). For comparison, by using an existing metal paste (heating element material), patterns having four different line widths were simultaneously formed on a ceramic green sheet by screen printing (sample 22). The four different lines widths were 0.18 mm, 0.36 mm, 0.72 mm, and 1.10 mm. The average thicknesses of the patterns having the line widths were measured.

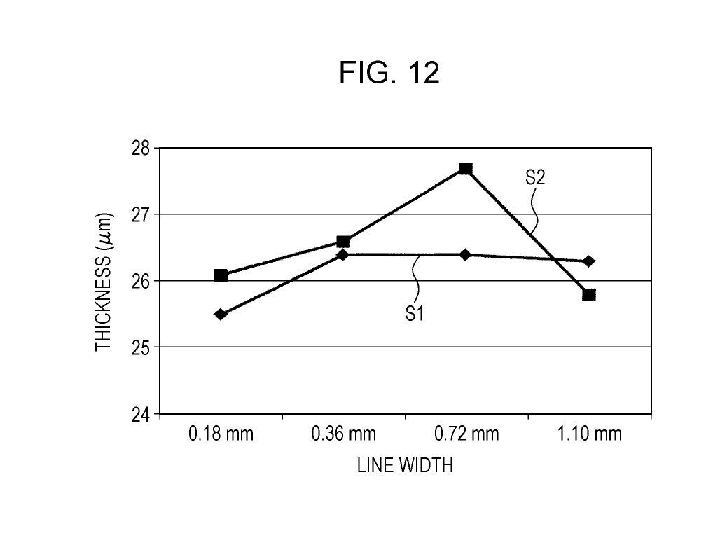

FIG. 12 is a graph representing the relationships between the line width and the thickness of the heating element materials of the sample 12 and the sample 22. In FIG. 12, S1 represents the result for the sample 12, and S2 represents the result for the sample 22. It can be seen from FIG. 12 that, for the sample 12 (S1), which was formed by photolithography, the difference in thickness between patterns having different line widths was small. Thus, it can be seen that, even if a pattern included lines having different line widths, variation in the thickness of the pattern in the sample 12 (S1), which was formed by photolithography, was suppressed, compared with the sample 22 (S2), which was formed by screen printing.

Next, by using the photosensitive metal paste (heating element material), patterns having three different line widths were formed on a ceramic green sheet by photolithography. A plurality of ceramic sheets, including this ceramic green sheet, were stacked, thermal-compression bonded, and fired under predetermined conditions to obtain a body substrate including a heating element (sample 13). For comparison, by using an existing metal paste (heating element material), patterns having three different line widths were formed on a ceramic green sheet by screen printing. A plurality of ceramic sheets including this ceramic green sheet were stacked, thermal-compression bonded, and fired under predetermined conditions to obtain a body substrate including a heating element (sample 23). A cross section of each of these body substrates (in particular, the cross-sectional shape of the heating element) was observed.

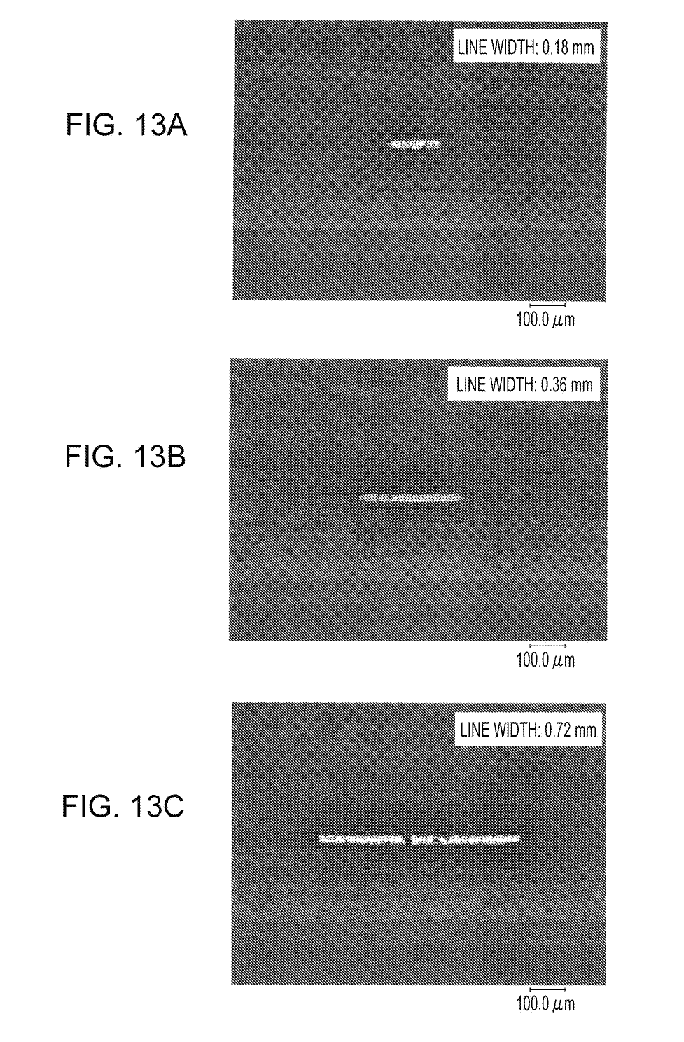

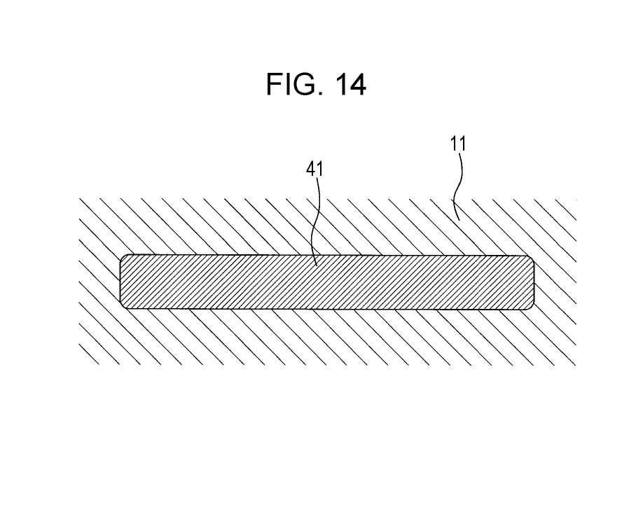

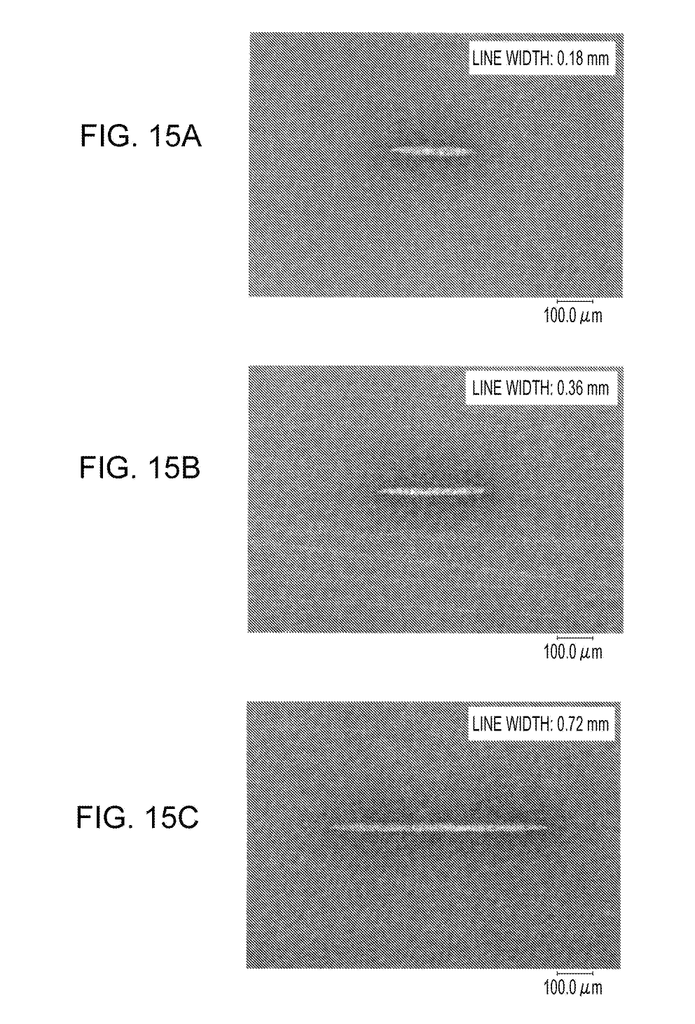

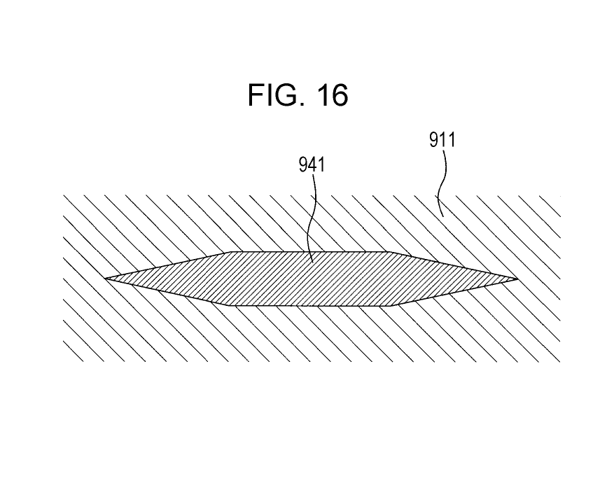

FIGS. 13A to 13C are photographs showing the cross-sectional shapes of the heating elements (having line widths 0.18 mm, 0.36 mm, and 0.72 mm) of the sample 13. FIG. 14 is a schematic view illustrating the cross-sectional shape of the heating elements of the sample 13. FIGS. 15A to 15C are photographs showing the cross-sectional shapes of the heating elements (having line widths 0.18 mm, 0.36 mm, and 0.72 mm) of the sample 23. FIG. 16 is a schematic view illustrating the cross-sectional shape of the heating elements of the sample 23.

Referring to FIGS. 13A to 13C, the cross-sectional shape of the heating elements of the sample 13 was rectangular. That is, as shown in FIG. 14, the cross-sectional shape of the heating element 41, which was disposed in the body substrate 11, was rectangular. The corners of the rectangle were slightly rounded. The line width and the thickness of the heating element 41 were substantially constant.

Referring to FIGS. 15A to 15C, in contrast, both end portions of the heating elements of the sample 23 in the width direction had triangular points. That is, as shown in FIG. 16, both end portions of a heating element 941, which is disposed in a body substrate 911, in the width direction are pointed triangularly. The thicknesses of the end portions of the heating element 941 in the width direction decrease toward the pointed ends.

From these results, it can be seen that variations in the thickness and the width of the heating element of the sample 13 (in which the patterns were formed by photolithography) are small and the heating element can generate heat uniformly, compared with the heating element of the sample 23 (in which the patterns were formed by screen printing).

### C. Other Embodiments

The present invention is not limited to the embodiments, the example, and other matters described above. Needless to say, the present invention can be carried out in various ways within the spirit and scope thereof.

(1) In the embodiments described above, in the application step, the photosensitive metal paste is applied onto the ceramic green sheet by screen printing. Alternatively, for example, a metal mask may be disposed on the ceramic green sheet, and, in the application step, the photosensitive metal paste may be applied through the metal mask or may be applied by using a coater or the like.

(2) In the embodiments described above, the heating element is disposed in the body substrate. Alternatively, for example, the heating element may be disposed on a surface of the body substrate. Likewise, the attraction electrode, which is disposed in the body substrate in the embodiments, may be disposed, for example, on a surface of the body substrate.

(3) In the embodiments described above, a “negative” photosensitive metal paste, with which exposed portions remain when development is performed, is used as the photosensitive metal paste. Alternatively, a “positive” photosensitive metal paste, with which exposed portions are removed when developed is performed, may be used.

What is claimed is:

1. A method of making a semiconductor manufacturing equipment component including a body substrate made of a ceramic and a heating element disposed in the body substrate, the method comprising:
an application step of applying a photosensitive metal paste onto a ceramic green sheet, the photosensitive metal paste being a heating element material;
an exposure-and-development step of exposing to light the photosensitive metal paste that has been applied onto the ceramic green sheet and developing the photosensitive metal paste to form an intermediate heating element on the ceramic green sheet; and
a firing step of co-firing the ceramic green sheet and the intermediate heating element whereupon the ceramic green sheet becomes the body substrate and the intermediate heating element becomes the heating element disposed in the body substrate.

2. A method of making a semiconductor manufacturing equipment component including a body substrate made of a ceramic and a heating element disposed in the body substrate, the method comprising:
an application step of applying a photosensitive metal paste onto a carrier film, the photosensitive metal paste being a heating element material;
an exposure-and-development step of exposing to light the photosensitive metal paste that has been applied onto the carrier film and developing the photosensitive metal paste to form an intermediate heating element on the carrier film;
a transfer step of transferring the intermediate heating element on the carrier film onto a ceramic green sheet; and
a firing step of co-firing the ceramic green sheet and the intermediate heating element whereupon the ceramic green sheet becomes the body substrate and the intermediate heating element becomes the heating element disposed in the body substrate.

3. The method according to claim 1, wherein the intermediate heating element has a rectangular cross section.

4. The method according to claim 1, wherein the intermediate heating element has a surface roughness Ra that is 1 μm or less.

5. A semiconductor manufacturing equipment component comprising:
a body substrate made of a ceramic; and
a heating element disposed in the body substrate;
wherein the heating element has a rectangular cross section.

6. The semiconductor manufacturing equipment component according to claim 5,
wherein the heating element has a surface roughness Ra that is 1 μm or less.

7. The method according to claim 3, wherein the intermediate heating element has a surface roughness Ra that is 1 μm or less.

8. The method according to claim 2, wherein the intermediate heating element has a rectangular cross section.

9. The method according to claim 2, wherein the intermediate heating element has a surface roughness Ra that is 1 μm or less.

10. The method according to claim 8, wherein the intermediate heating element has a surface roughness Ra that is 1 μm or less.
